(19) United States
(12) Patent Application Publication
(10) Pub. No.: US 2010/0006923 A1
(43) Pub. Date: Jan. 14, 2010

(54) SEMICONDUCTOR DEVICE AND METHOD FOR MANUFACTURING THE SAME

(76) Inventors: Ryota FUJITSUKA, Yokohama-shi (JP); Katsuyuki SEKINE, Yokohama-shi (JP); Yoshio OZAWA, Yokohama-shi (JP); Daisuke NISHIDA, Yokkaichi-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/498,916

(22) Filed: Jul. 7, 2009

(30) Foreign Application Priority Data
Jul. 8, 2008 (JP) 2008-178168

(51) Int. Cl. H01L 29/792; H01L 21/28

(52) U.S. Cl. 257/324; 438/591; 257/E29.309; 257/E21.21

(57) ABSTRACT

A semiconductor device includes a tunnel insulating film formed on a surface of a semiconductor region, a charge storage insulating film formed on a surface of the tunnel insulating film, a block insulating film formed on a surface of the charge storage insulating film, and a control gate electrode formed on a surface of the block insulating film, wherein the block insulating film includes a first insulating film containing a metal element and oxygen as main components, a second insulating film containing silicon and oxygen as main components, and an interface layer formed between the first insulating film and the second insulating film and containing the metal element, silicon, and oxygen as main components.

### CROSS-REFERENCE TO RELATED APPLICATIONS

This application is based upon and claims the benefit of priority from prior Japanese Patent Application No. 2008-178168, filed Jul. 8, 2008, the entire contents of which are incorporated herein by reference.

### BACKGROUND OF THE INVENTION

1. Field of the Invention

The present invention relates to a semiconductor device and a method for manufacturing the semiconductor device.

2. Description of the Related Art

A charge trap type nonvolatile semiconductor memory has been proposed in which a charge storage insulating film for charge trapping is used as a charge storage layer (see Jpn. Pat. Appln. KOKAI Publication No. 2004-158810). In the charge trap type nonvolatile semiconductor memory, charges injected into the charge storage insulating film through a tunnel insulating film are trapped in a trap state in the charge storage insulating film. The charges are thus stored in the charge storage insulating film. A known typical charge trap type nonvolatile semiconductor memory is of a MONOS or SONOS type.

However, in the charge trap type nonvolatile semiconductor memory, the configuration of a block insulating film provided between the charge storage insulating film and a control gate electrode and a method for forming the block insulating film are not sufficiently optimized.

### BRIEF SUMMARY OF THE INVENTION

A first aspect of the present invention provides a semiconductor device comprising: a tunnel insulating film formed on a surface of a semiconductor region; a charge storage insulating film formed on a surface of the tunnel insulating film; a block insulating film formed on a surface of the charge storage insulating film; and a control gate electrode formed on a surface of the block insulating film, wherein the block insulating film includes a first insulating film containing a metal element and oxygen as main components, a second insulating film containing silicon and oxygen as main components, and an interface layer formed between the first insulating film and the second insulating film and containing the metal element, silicon, and oxygen as main components.

A second aspect of the present invention provides a semiconductor device comprising: a tunnel insulating film formed on a surface of a semiconductor region; a charge storage insulating film formed on a surface of the tunnel insulating film; a block insulating film formed on a surface of the charge storage insulating film; and a control gate electrode formed on a surface of the block insulating film, wherein the block insulating film includes a first insulating film containing a metal element and oxygen as main components, a second insulating film containing silicon and oxygen as main components, and an interface layer formed between the first insulating film and the second insulating film and containing nitrogen, and the interface layer has a higher nitrogen concentration than each of the first insulating film and the second insulating film.

A third aspect of the present invention provides a semiconductor device comprising: a tunnel insulating film formed on a surface of a semiconductor region; a charge storage insulating film formed on a surface of the tunnel insulating film; a block insulating film formed on a surface of the charge storage insulating film; and a control gate electrode formed on a surface of the block insulating film, wherein the block insulating film includes a first insulating film containing a metal element and oxygen as main components, a second insulating film containing silicon and oxygen as main components, and an interface layer formed between the first insulating film and the second insulating film and containing a predetermined element selected from inert gas elements and halogen elements, and the predetermined element in the interface layer has a higher concentration than that in each of the first insulating film and the second insulating film.

A fourth aspect of the present invention provides a method for manufacturing a semiconductor device comprising a tunnel insulating film formed on a surface of a semiconductor region, a charge storage insulating film formed on a surface of the tunnel insulating film, a block insulating film formed on a surface of the charge storage insulating film, and a control gate electrode formed on a surface of the block insulating film, forming the block insulating film comprising: forming a first insulating film containing a metal element and oxygen as main components; forming a second insulating film containing silicon and oxygen as main components, on a surface of the first insulating film; and carrying out thermal treatment on the first insulating film and the second insulating film in an oxidizing atmosphere.

A fifth aspect of the present invention provides a method for manufacturing a semiconductor device comprising a tunnel insulating film formed on a surface of a semiconductor region, a charge storage insulating film formed on a surface of the tunnel insulating film, a block insulating film formed on a surface of the charge storage insulating film, and a control gate electrode formed on a surface of the block insulating film, forming the block insulating film comprising: forming a first insulating film containing a metal element and oxygen as main components, in a first depositing atmosphere; forming a second insulating film containing silicon and oxygen as main components, on a surface of the first insulating film; and forming a third insulating film containing a metal element and oxygen as main components, on a surface of the second insulating film in a second depositing atmosphere exerting higher oxidizing power than the first depositing atmosphere.

### BRIEF DESCRIPTION OF THE SEVERAL VIEWS OF THE DRAWING

FIGS. 1A and 1B are sectional views schematically showing a part of a basic method for manufacturing a semiconductor device according to a first embodiment of the present invention;

FIGS. 2A and 2B are sectional views schematically showing a part of the basic method for manufacturing the semiconductor device according to the first embodiment of the present invention;

FIGS. 3A and 3B are sectional views schematically showing a part of the basic method for manufacturing the semiconductor device according to the first embodiment of the present invention;

FIGS. 4A and 4B are sectional views schematically showing a part of the basic method for manufacturing the semiconductor device according to the first embodiment of the present invention;

FIGS. 5A and 5B are sectional views schematically showing a part of the basic method for manufacturing the semiconductor device according to the first embodiment of the present invention;

FIG. 6 is a sectional view schematically showing the configuration of a block insulating film according to the first embodiment of the present invention in detail;

FIG. 7 is a diagram schematically showing the distribution of charge trap state densities in the block insulating film according to the first embodiment of the present invention;

FIG. 8 is a diagram showing an energy band structure observed during a write operation according to the first embodiment of the present invention;

FIG. 9 is a diagram showing an energy band structure observed during a write operation in a comparative example of the first embodiment of the present invention;

FIGS. 10A and 10B are sectional views schematically showing a part of a manufacturing method in a first specific example of the first embodiment of the present invention;

FIG. 11 is a diagram showing the relationship between a thermal treatment temperature and the leakage current density of the block insulating film;

FIGS. 12A and 12B are sectional views schematically showing a part of a manufacturing method in a second specific example of the first embodiment of the present invention;

FIGS. 13A, 13B, and 13C are sectional views schematically showing a part of a manufacturing method in a third specific example of the first embodiment of the present invention;

FIGS. 14A, 14B, and 14C are sectional views schematically showing a part of a manufacturing method in a fourth specific example of the first embodiment of the present invention;

FIGS. 15A, 15B, and 15C are sectional views schematically showing the configuration of a modification of the first embodiment of the present invention;

FIGS. 16A and 16B are sectional views schematically showing a part of a method for manufacturing a semiconductor device according to a second embodiment of the present invention;

FIG. 17 is a diagram showing the dependence of a charge retention characteristic on the thermal treatment temperature according to the second embodiment of the present invention;

FIG. 18 is a diagram showing the relationship between the thermal treatment temperature and the electrical film thickness of the whole insulating film;

FIGS. 19A and 19B are sectional views schematically showing a part of a method for manufacturing a semiconductor device according to a third embodiment of the present invention;

FIG. 20 is a sectional view schematically showing the configuration of a semiconductor device according to a fourth embodiment of the present invention; and

FIG. 21 is a plan view schematically showing the configuration of the semiconductor device according to the fourth embodiment of the present invention.

### DETAILED DESCRIPTION OF THE INVENTION

Embodiments of the present invention will be described with reference to the drawings. In each of the embodiments described below, a charge trap type nonvolatile semiconductor memory will be described in which a charge storage insulating film for charge trapping is used as a charge storage layer.

### Embodiment 1

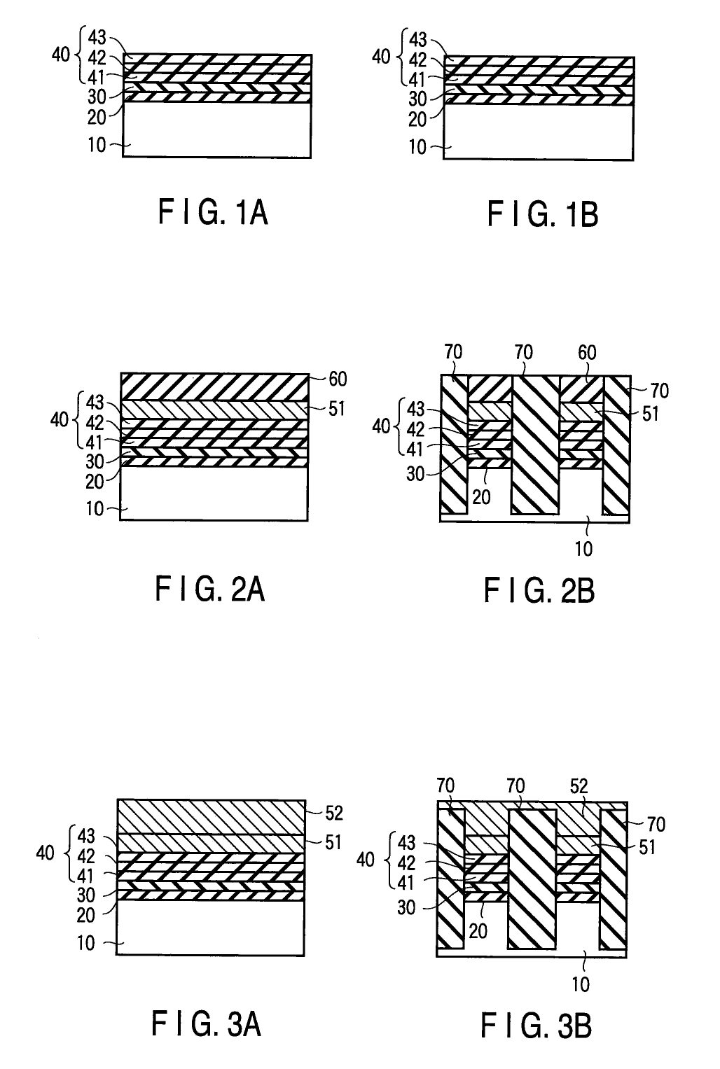

FIGS. 1A and 1B to FIGS. 5A and 5B are sectional views schematically showing a basic method for manufacturing a semiconductor device (nonvolatile semiconductor memory) according to the present embodiment. FIGS. 1A to 5A are sectional views taken along a channel length direction (bit line direction). FIGS. 1B to 5B are sectional views taken along a channel width direction (word line direction).

First, as shown in FIGS. 1A and 1B, a silicon oxide film of thickness about 5 nm is formed, as a tunnel insulating film 20, on a semiconductor substrate (silicon substrate) 10 doped with a predetermined impurity element, by means of a thermal oxidation method. Subsequently, a silicon nitride film of thickness about 5 nm is formed, as a charge storage insulating film 30, on the tunnel insulating film 20 by a CVD (Chemical Vapor Deposition) method.

Then, a block insulating film 40 is formed on the charge storage insulating film 30; in the block insulating film 40, a lower insulating film 41, an intermediate insulating film 42, and an upper insulating film 43 are stacked. The block insulating film 40 includes an interface layer (not shown in the drawings) formed between the lower insulating film 41 and the intermediate insulating film 42, and an interface layer (not shown in the drawings) formed between the upper insulating film 43 and the intermediate insulating film 42. The configuration of the block insulating film 40 and a method for forming the block insulating film 40 will be described in detail.

Then, as shown in FIGS. 2A and 2B, a polysilicon film of thickness about 30 nm is formed, as a lower control gate electrode film 51, on the block insulating film 40 by the CVD method. A mask film 60 is formed on the lower control gate electrode film 51 by the CVD method. A photo resist pattern (not shown in the drawings) extending in the bit line direction is formed on the mask film 60. The photo resist pattern is used as a mask to etch the mask film 60, the lower control gate electrode film 51, the block insulating film 40, the charge storage insulating film 30, the tunnel insulating film 20, and the semiconductor substrate 10 by an RIE (Reactive Ion Etching) method. As a result, isolation trenches of depth about 100 nm extending in the bit line direction are formed, with an element region between the adjacent isolation trenches. The width of the isolation trench and the width of the element region are both about 50 nm. Thereafter, a silicon oxide film is deposited, as an isolation insulating film, on the entire resulting surface to fill the isolation trenches with the isolation insulating film. The isolation insulating film is further flattened by a CMP (Chemical Mechanical Polishing) method to expose the mask film 60. Thus, isolation regions 70 with the isolation trenches filled with the isolation insulating film is obtained.

Then, as shown in FIGS. 3A and 3B, the mask film 60 is selectively removed by wet etching to expose the lower control gate electrode film 51. A stack film of polycrystalline silicon and tungsten silicide (thickness: about 100 nm) is subsequently formed, as an upper control gate electrode film 52, on the entire resulting surface by the CVD method.

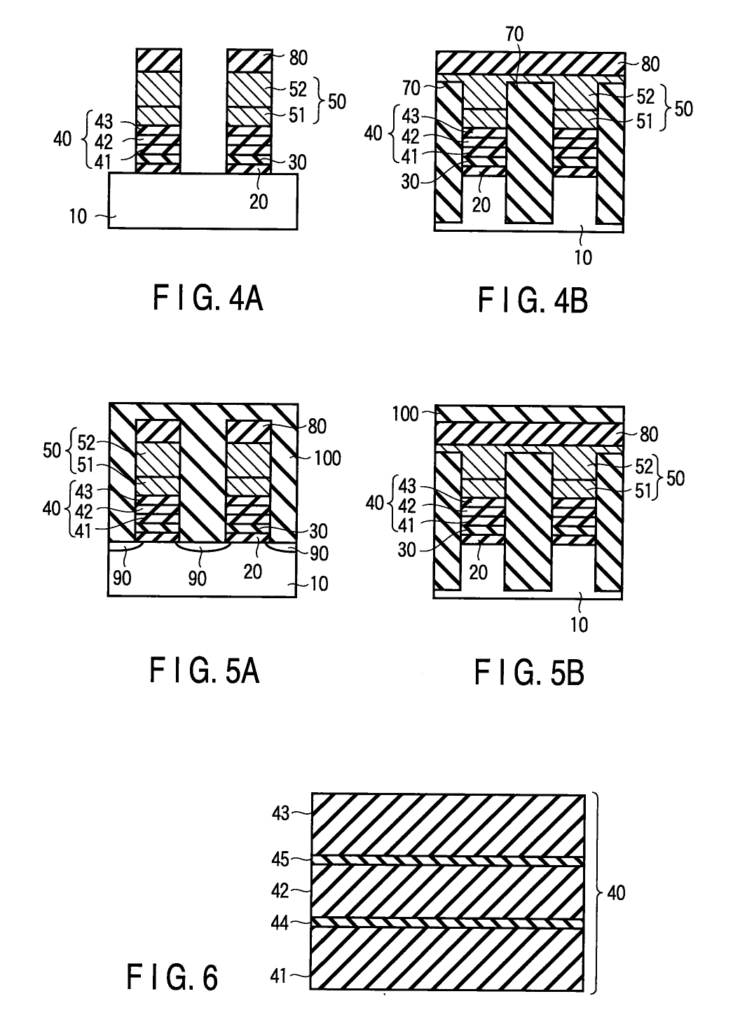

Then, as shown in FIGS. 4A and 4B, a silicon nitride film is formed, as a mask film 80, by the CVD method. A photo resist pattern (not shown in the drawings) extending in the word line direction is further formed on the mask film 80. The photo resist pattern is used as a mask to etch the mask film 80, the upper control gate electrode film 52, the lower control gate electrode film 51, the block insulating film 40, the charge storage insulating film 30, and the tunnel insulating film 20 by the RIE method. Thus, a pattern of a control gate electrode 50 is obtained which is formed of the lower control gate electrode film 51 and the upper control gate electrode film 52. The pattern width of the control gate electrode 50 and the space width of the control gate width 50 are both about 50 nm.

Then, as shown in FIGS. 5A and 5B, the gate structure obtained as described above is used as a mask to ion-implant an impurity element into the surface region of the semiconductor substrate 10. Thermal treatment is further carried out to form a source/drain region (impurity diffusion layer) 90. As described above, a charge trap type memory cell transistor is obtained which includes the tunnel insulating film 20 formed on the surface of the semiconductor substrate (semiconductor region) 10, the charge storage insulating film 30 formed on the surface of the tunnel insulating film 20, the block insulating film 40 formed on the surface of the charge storage insulating film 30, the control gate electrode 50 formed on the surface of the block insulating film 40, and the source/drain region (impurity diffusion layer) 90. Thereafter, an interlayer insulating film 100 is formed by the CVD method. Moreover, a well-known technique is used to form wiring and the like to obtain a semiconductor device (nonvolatile semiconductor memory).

In the above-described charge trap type nonvolatile semiconductor memory cell (memory cell transistor), an appropriate voltage is applied to between the control gate electrode 50 and the semiconductor substrate 10 to cause charging and discharging between the semiconductor substrate 10 and the charge storage insulating film 30 via the tunnel insulating film 20. Specifically, charges injected into the charge storage insulating film 30 through the tunnel insulating film 20 are trapped in the trap state in the charge storage insulating film 30. The charges are stored in the charge storage insulating film 30.

In the above-described semiconductor device, as shown in FIG. 5B, the charge storage insulating film 30 and the block insulating film 40 are divided by the isolation regions 70. However, a configuration can also be adopted in which the charge storage insulating film 30 and the block insulating film 40 are not divided by the isolation regions 70.

FIG. 6 is a sectional view schematically showing the configuration of the block insulating film 40 in detail.

The block insulating film 40 has a stack structure including a lower insulating film 41, an intermediate insulating film 42, and an upper insulating film 43. The lower insulating film 41 and the upper insulating film 43 contain at least a metal element and oxygen as main components. In general, a metal oxide film is used as the lower insulating film 41 and the upper insulating film 43. The intermediate insulating film 42 contains at least silicon and oxygen as main components. In general, a silicon oxide film is used as the intermediate insulating film 42. The intermediate insulating film 42 may contain an element such as nitrogen. The lower insulating film 41 and the upper insulating film 43 have a higher dielectric constant than the intermediate insulating film 42. The block insulating film 40 includes an interface layer 44 formed between the lower insulating film 41 and the intermediate insulating film 42, and an interface layer 45 between the upper insulating film 43 and the intermediate insulating film 42.

As described above, the block insulating film 40 has a stack structure including the lower insulating film 41, the intermediate insulating film 42, and the upper insulating film 43. The metal oxide film used as the lower insulating film 41 and the upper insulating film 43 has a high dielectric constant and offers a high leakage resistance (high-field leakage resistance) when a high electric field (high voltage) is applied to the films. However, the metal oxide film has a higher trap state density than the silicon oxide film. Thus, the metal oxide film offers a lower leakage resistance (low-field leakage resistance) than the silicon oxide film when a low electric field (low voltage) is applied to the film. The block insulating film 40 according to the present embodiment has a stack structure including the lower insulating film 41 containing a metal oxide as a main component, the intermediate insulating film 42 containing a silicon oxide as a main component, and the upper insulating film 43 containing a metal oxide as a main component. Thus, the lower insulating film 41 and the upper insulating film 43 ensure the high-field leakage resistance, whereas the intermediate insulating film 42 ensures the low-field leakage resistance. This inhibits a possible leakage current from the block insulating film 40. Furthermore, as described below, the interface layers 44 and 45 enables further inhibition of the possible leakage current.

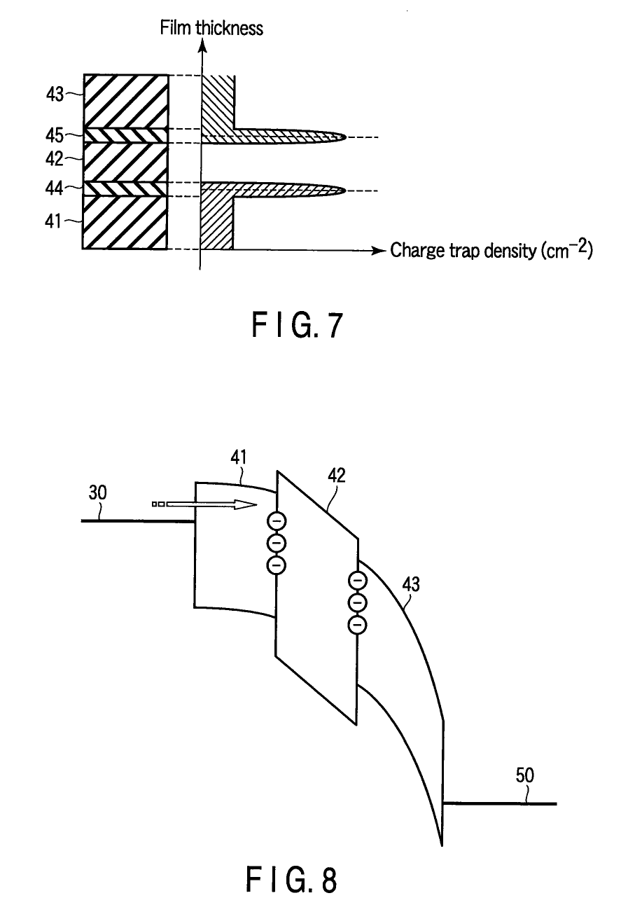

FIG. 7 is a diagram schematically showing the distribution of charge trap state densities in the block insulating film 40 shown in FIG. 6. As shown in FIG. 7, the intermediate insulating film 42 has a much lower trap state density than the lower insulating film 41 and the upper insulating film 43. The interface layers 44 and 45 have a much higher trap state density than the intermediate insulating film 42, the lower insulating film 41, and the upper insulating film 43. For example, the interface layers 44 and 45 have a trap state density of about 1×10¹¹ to 1×10¹⁵/cm².

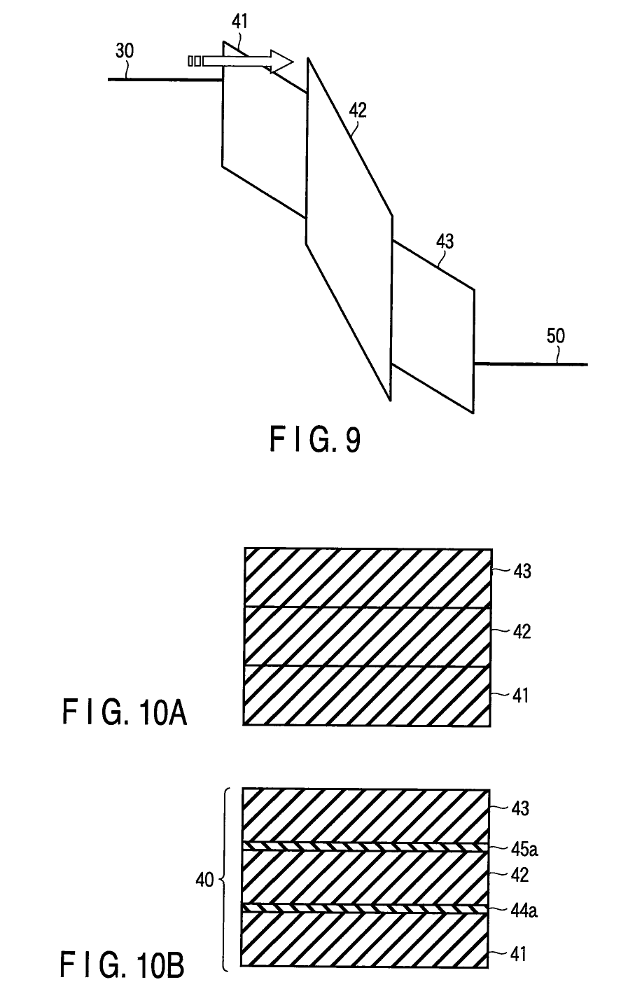

FIG. 8 is a diagram showing an energy band structure observed during a write operation in the memory cell transistor according to the present embodiment. FIG. 9 is a diagram showing an energy band structure observed during a write operation in a memory cell transistor in a comparative example of the present embodiment.

As described above, in the memory cell transistor according to the present embodiment, as shown in FIG. 6, the interface layer 44 is formed between the lower insulating film 41 and the intermediate insulating film 42. Furthermore, the interface layer 45 is formed between the upper insulating film 43 and the intermediate insulating film 42. Thus, as shown in FIG. 8, charges (in the illustrated example, electrons) are trapped in the trap state in the interface layers 44 and 45 in association with the write operation. As a result, the trapped charges (in particular, the charges trapped in the interface layer 44) weaken an electric field applied to the lower insulating film 41. Thus, a barrier effect on the possible tunnel current is improved, allowing the possible leakage current from the block insulating film to be inhibited.

Even during an erase operation in the memory cell transistor, the possible leakage current from the block insulating film is inhibited based on a principle similar to that described above. That is, charges are trapped in the trap state in the interface layers 44 and 45 in association with the erase operation. The trapped charges (in particular, the charges trapped in the interface layer 45) weaken an electric field applied to the upper insulating film 43. As a result, the barrier effect on the possible tunnel current is improved, allowing the possible leakage current from the block insulating film to be inhibited.

Furthermore, the interface layer 44 is formed at the interface between the lower insulating film 41 and the intermediate insulating film 42. The interface layer 45 is formed at the interface between the upper insulating film 43 and the intermediate insulating film 42. Thus, each of the interface layers 44 and 45 is located at given distances from the charge storage insulating film 30 and the control gate electrode 50. Thus, a charge retention characteristic can be inhibited from being degraded by detrapping of the charges.

As described above, the block insulating film 40 according to the present embodiment has the stack structure including the lower insulating film 41, the intermediate insulating film 42, and the upper insulating film 43, as well as the interface layers 44 and 45, having a high trap state density. Thus, the possible leakage current from the block insulating film 40 can be drastically inhibited, providing a reliable nonvolatile semiconductor memory with excellent characteristics.

Now, description will be given of the specific configuration of the memory cell transistor according to the present embodiment and a specific method for manufacturing the memory cell transistor.

### Specific Example 1

FIGS. 10A and 10B are sectional views schematically showing a part of a manufacturing method in a first specific example of the present embodiment. A basic manufacturing method in this example is similar to that shown in FIGS. 1A and 1B to FIGS. 5A and 5B. Thus, a method for manufacturing a block insulating film will be mainly described.

A charge storage insulating film 30 is formed in the step shown in FIGS. 1A and 1B. Then, as shown in FIG. 10A, a metal oxide film serving as a lower insulating film 41 in a block insulating film is formed on the charge storage insulating film 30. An aluminum oxide film (alumina film) is used as the metal oxide film. Specifically, an alumina film 41 of thickness about 4 nm is formed at a deposition temperature of 300° C. by an ALD (Atomic Layer Deposition) method using trimethyl aluminum and steam as a source gas. Thermal treatment is carried out in a nitrogen atmosphere at 1,000° C. for one minute. A silicon oxide film serving as an intermediate insulating film 42 in the block insulating film is then formed on the alumina film 41. Specifically, a silicon oxide film 42 of thickness about 3 nm is formed at a deposition temperature of 800° C. by the CVD (Chemical Vapor Deposition) method using nitrogen monoxide and dichlorosilane as a source gas. A metal oxide film serving as an upper insulating film 43 in the block insulating film is formed on the silicon oxide film 42. An alumina film is used as the metal oxide film. An alumina film 43 of thickness about 4 nm is formed by the ALD method. Specific deposition conditions for the alumina film 43 are the same as those for the above-described alumina film 41.

Then, as shown in FIG. 10B, thermal treatment is carried out in a nitrogen atmosphere at 1,000° C. for one minute. The thermal treatment allows an interface layer 44a to be formed at the interface between the alumina film (lower insulating film) 41 and the silicon oxide film (intermediate insulating film) 42 and an interface layer 45a between the alumina film (upper insulating film) 43 and the silicon oxide film (intermediate insulating film) 42. Both the interface layers 44a and 45a contain aluminum, silicon, and oxygen as main components. That is, aluminum silicate is formed as a result of the interfacial reaction between the alumina film and the silicon oxide film associated with the thermal treatment. Generally speaking, the interface layer 44a contains silicon, oxygen, and the metal element contained in the lower insulating film 41, as main components. The interface layer 45a contains silicon, oxygen, and the metal element contained in the upper insulating film 43, as main components.

Subsequent steps are similar to those shown in FIGS. 2A and 2B to FIGS. 5A and 5B. Thus, such a memory cell transistor as shown in FIGS. 5A and 5B is formed.

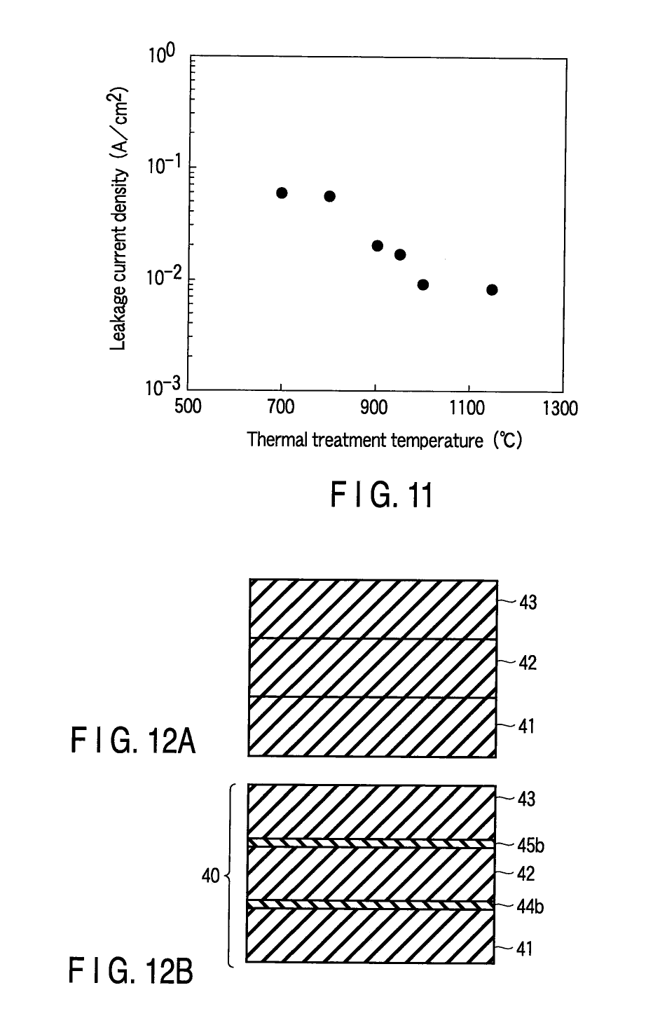

FIG. 11 is a diagram showing the relationship between the thermal treatment temperature in the step shown in FIG. 10B and the leakage current density of the block insulating film 40. An electric field equivalent to that provided during the write operation is applied to the block insulating film 40. As shown in FIG. 11, an increase in thermal treatment temperature reduces the possible leakage current. This is because the aluminum silicate, serving as a charge trapping source, is more likely to be formed at higher thermal treatment temperatures. However, at a thermal treatment temperature of at least 1,100° C., thermal degradation may occur to reduce the reliability of the memory cell transistor. Thus, the thermal treatment temperature is preferably between 900° C. and 1,100° C.

As described above, in the present specific example, after the formation of the alumina film (lower insulating film) 41, the silicon oxide film (intermediate insulating film) 42, and the alumina film (upper insulating film) 43, the thermal treatment is carried out to cause the interfacial reaction. The metal silicate formed by the interfacial reaction serves as the interface layers 44a and 45a, having a high trap state density. Therefore, as described above, the possible leakage current from the block insulating film 40 can be drastically inhibited, providing a reliable nonvolatile semiconductor memory with excellent characteristics.

### Specific Example 2

FIGS. 12A and 12B are sectional views schematically showing a part of a manufacturing method in a second specific example of the present embodiment. A basic manufacturing method in this example is similar to that shown in FIGS. 1A and 1B to FIGS. 5A and 5B. Thus, a method for manufacturing a block insulating film will be mainly described.

A charge storage insulating film 30 is formed in the step shown in FIGS. 1A and 1B. Then, as shown in FIG. 12A, an amorphous metal oxide film serving as a lower insulating film 41 in a block insulating film is formed on the charge storage insulating film 30. A hafnium oxide film is used as the metal oxide film. Specifically, a hafnium oxide film 41 of thickness about 4 nm is formed at a deposition temperature of 200° C. by the ALD method using tetra ethyl methyl aminohafnium and steam as a source gas. A silicon oxide film serving as an intermediate insulating film 42 in the block insulating film is subsequently formed on the hafnium oxide film 41. Specifically, a silicon oxide film 42 of thickness about 3 nm is formed at a deposition temperature of 800° C. by the CVD method using nitrogen monoxide and dichlorosilane as a source gas. An amorphous metal oxide film serving as an upper insulating film 43 in the block insulating film is subsequently formed on the silicon oxide film 42. A hafnium oxide film is used as the metal oxide film. A hafnium oxide film 43 of thickness about 4 nm is formed by the ALD method. Specific deposition conditions for the hafnium oxide film 43 are the same as those for the above-described hafnium oxide film 41.

Then, as shown in FIG. 12B, thermal treatment is carried out in a nitrogen atmosphere at 800° C. for one minute. The thermal treatment allows an interface layer 44b to be formed at the interface between the hafnium oxide film (lower insulating film) 41 and the silicon oxide film (intermediate insulating film) 42 and an interface layer 45b between the hafnium oxide film (upper insulating film) 43 and the silicon oxide film (intermediate insulating film) 42. Both the interface layers 44b and 45b contain hafnium, silicon, and oxygen as main components. That is, hafnium silicate is formed as a result of the interfacial reaction between the hafnium oxide film and the silicon oxide film associated with the thermal treatment. Thus, the interface layers 44b and 45b are formed. Generally speaking, the interface layer 44b contains silicon, oxygen, and the metal element contained in the lower insulating film 41, as main components. The interface layer 45b contains silicon, oxygen, and the metal element contained in the upper insulating film 43, as main components.

Subsequent steps are similar to those shown in FIGS. 2A and 2B to FIGS. 5A and 5B. Thus, such a memory cell transistor as shown in FIGS. 5A and 5B is formed.

In the present specific example, the lower insulating film 41 and the upper insulating film 43 are formed of the amorphous hafnium oxide film. As a result of the thermal treatment in FIG. 12B, the hafnium oxide films 41 and 43 are crystallized, whereas the silicon oxide film (intermediate insulating film) 42 maintains the amorphous state. Thus, distortion may be caused by stress at the interface between the hafnium oxide film 41 and the silicon oxide film 42 and at the interface between the hafnium oxide film 43 and the silicon oxide film 42. As a result, a region with a high trap state density is formed at the interface. Therefore, the possible leakage current from the block insulating film 40 can be inhibited, providing a reliable nonvolatile semiconductor memory with excellent characteristics.

### Specific Example 3

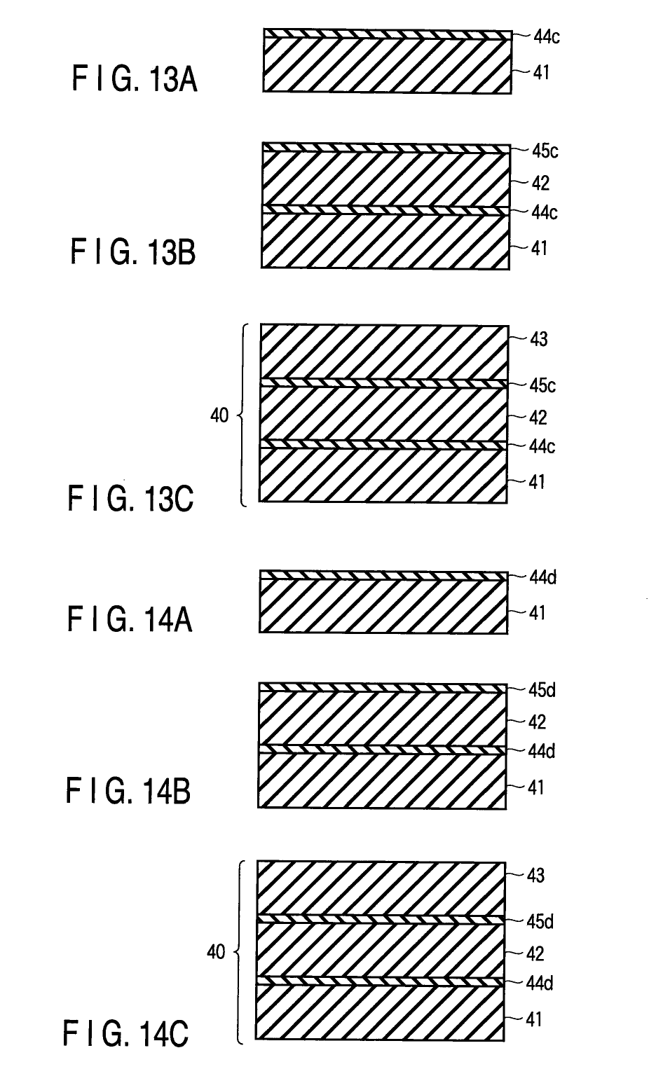

FIGS. 13A, 13B, and 13C are sectional views schematically showing a part of a manufacturing method in a third specific example of the present embodiment. A basic manufacturing method in this example is similar to that shown in FIGS. 1A and 1B to FIGS. 5A and 5B. Thus, a method for manufacturing a block insulating film will be mainly described.

A charge storage insulating film 30 is formed in the step shown in FIGS. 1A and 1B. Then, as shown in FIG. 13A, a metal oxide film serving as a lower insulating film 41 in a block insulating film is formed on the charge storage insulating film 30. A hafnium oxide film is used as the metal oxide film. Specifically, a hafnium oxide film 41 of thickness about 4 nm is formed at a deposition temperature of 300° C. by the ALD method using tetra ethyl methyl aminohafnium and steam as a source gas. A surface region of the hafnium oxide film 41 is subsequently nitrided by nitrogen radicals. The radical nitriding treatment is carried out in an atmosphere containing nitrogen at a pressure of 10 Pa and at a treatment temperature of 300° C. The radical nitriding treatment allows an interface layer 44c containing nitrogen to be formed on the surface of the hafnium oxide film 41.

Then, as shown in FIG. 13B, a silicon oxide film serving as an intermediate insulating film 42 in the block insulating film is formed on the interface layer 44c. Specifically, a silicon oxide film 42 of thickness about 3 nm is formed at a deposition temperature of 800° C. by the CVD method using nitrogen monoxide and dichlorosilane as a source gas. A surface region of the silicon oxide film 42 is subsequently nitrided by nitrogen radicals. Conditions for the radical nitriding treatment are the same as those for the above-described hafnium oxide film 41. The radical nitriding treatment allows an interface layer 45c containing nitrogen to be formed on the surface of the silicon oxide film 42.

Then, as shown in FIG. 13C, a metal oxide film serving as an upper insulating film 43 in the block insulating film is formed on the interface layer 45c. A hafnium oxide film is used as the metal oxide film. A hafnium oxide film 43 of thickness about 4 nm is formed by the ALD method. Specific deposition conditions for the hafnium oxide film 43 are the same as those for the above-described hafnium oxide film 41.

As described above, a block insulating film 40 is obtained in which the interface layer 44c is formed at the interface between the hafnium oxide film (lower insulating film) 41 and the silicon oxide film (intermediate insulating film) 42 and in which the interface layer 45c is formed between the hafnium oxide film (upper insulating film) 43 and the silicon oxide film (intermediate insulating film) 42. Both the interface layers 44c and 45c have a higher nitrogen concentration that each of the hafnium oxide film (lower insulating film) 41, the silicon oxide film (intermediate insulating film) 42, and the hafnium oxide film (upper insulating film) 43.

Subsequent steps are similar to those shown in FIGS. 2A and 2B to FIGS. 5A and 5B. Thus, such a memory cell transistor as shown in FIGS. 5A and 5B is formed.

Thus, in the present specific example, the surface region of the hafnium oxide film (lower insulating film) 41 is nitrided to form the interface layer 44c. The surface region of the silicon oxide film (intermediate insulating film) 42 is nitrided to form the interface layer 45c. In the presence of nitrogen, a large number of charge traps are formed in the interface layers 44c and 45c. For example, introduced nitrogen allows a large number of dangling bonds to be generated. The dangling bonds serve as charge traps. As a result, the interface layers 44c and 45c have a high trap state density. Therefore, as already described, the possible leakage current from the block insulating film 40 can be drastically inhibited, providing a reliable nonvolatile semiconductor memory with excellent characteristics.

In the above-described example, the radical nitriding is used as a nitriding treatment. However, for example, thermal nitriding treatment may be used.

### Specific Example 4

FIGS. 14A, 14B, and 14C are sectional views schematically showing a part of a manufacturing method in a fourth specific example of the present embodiment. A basic manufacturing method in this example is similar to that shown in FIGS. 1A and 1B to FIGS. 5A and 5B. Thus, a method for manufacturing a block insulating film will be mainly described.

A charge storage insulating film 30 is formed in the step shown in FIGS. 1A and 1B. Then, as shown in FIG. 14A, a metal oxide film serving as a lower insulating film 41 in a block insulating film is formed on the charge storage insulating film 30. A hafnium oxide film is used as the metal oxide film. Specifically, a hafnium oxide film 41 of thickness about 4 nm is formed at a deposition temperature of 300° C. by the ALD method using tetra ethyl methyl aminohafnium and steam as a source gas. Thermal treatment is subsequently carried out in an argon gas atmosphere at 1,000° C. for one minute. The thermal treatment allows an interface layer 44d containing Argon (Ar) to be formed on the surface of the hafnium oxide film 41.

Then, as shown in FIG. 14B, a silicon oxide film serving as an intermediate insulating film 42 in the block insulating film is formed on the interface layer 44c. Specifically, a silicon oxide film 42 of thickness about 3 nm is formed at a deposition temperature of 800° C. by the CVD method using nitrogen monoxide and dichlorosilane as a source gas. Thermal treatment is subsequently carried out in an argon gas atmosphere at 1,000° C. for one minute. This radical nitriding treatment allows an interface layer 45d containing Argon (Ar) to be formed on the surface of the silicon oxide film 42.

Then, as shown in FIG. 14C, a metal oxide film serving as an upper insulating film 43 in the block insulating film is formed on the interface layer 45d. A hafnium oxide film is used as the metal oxide film. A hafnium oxide film 43 of thickness about 4 nm is formed by the ALD method. Specific deposition conditions for the hafnium oxide film 43 are the same as those for the above-described hafnium oxide film 41.

As described above, a block insulating film 40 is obtained in which the interface layer 44d is formed at the interface between the hafnium oxide film (lower insulating film) 41 and the silicon oxide film (intermediate insulating film) 42 and in which the interface layer 45d is formed between the hafnium oxide film (upper insulating film) 43 and the silicon oxide film (intermediate insulating film) 42. Both the interface layers 44d and 45d have a higher argon concentration than each of the hafnium oxide film (lower insulating film) 41, the silicon oxide film (intermediate insulating film) 42, and the hafnium oxide film (upper insulating film) 43.

Subsequent steps are similar to those shown in FIGS. 2A and 2B to FIGS. 5A and 5B. Thus, such a memory cell transistor as shown in FIGS. 5A and 5B is formed.

Thus, in the present specific example, the interface layer 44d containing argon is formed on the surface of the hafnium oxide film (lower insulating film) 41. The interface layer 45d containing argon is formed on the surface of the silicon oxide film (intermediate insulating film) 42. In the presence of argon, a large number of charge traps are formed in the interface layers 44d and 45d. For example, introduced argon distorts the network structure of atoms contained in the insulating film. The distorted portions serve as charge traps. As a result, the interface layers 44d and 45d have a high trap state density. Therefore, as already described, the possible leakage current from the block insulating film 40 can be drastically inhibited, providing a reliable nonvolatile semiconductor memory with excellent characteristics.

In the above-described example, the thermal treatment is carried out in the argon atmosphere. However, in general, the thermal treatment can be carried out in an atmosphere containing a predetermined element selected from inert gas elements and halogen elements. Even in this case, a configuration similar to that described above is obtained, and effects similar to those described above are obtained. For example, argon, krypton, or xenon may be used as an inert gas element, and bromine may be used as a halogen element. In particular, if an element with a large ion diameter is used, the above-described distortion of the network structure becomes significant. As a result, the trap state density of the interface layers 44d and 45d can be improved.

The first embodiment of the present invention has been described. However, the present embodiment may be modified as follows.

In the above-described embodiment, a layer with a high charge trap state density (interface layers 44 and 45) is provided only at the interface between the lower insulating film 41 and the intermediate insulating film 42 and at the interface between the upper insulating film 43 and the intermediate insulating film 42. However, a layer with a high charge trap state density may be formed in the intermediate insulating film 42 in addition to the interface layers 44 and 45. Even this configuration enables effects similar to those of the above-described embodiment to be exerted.

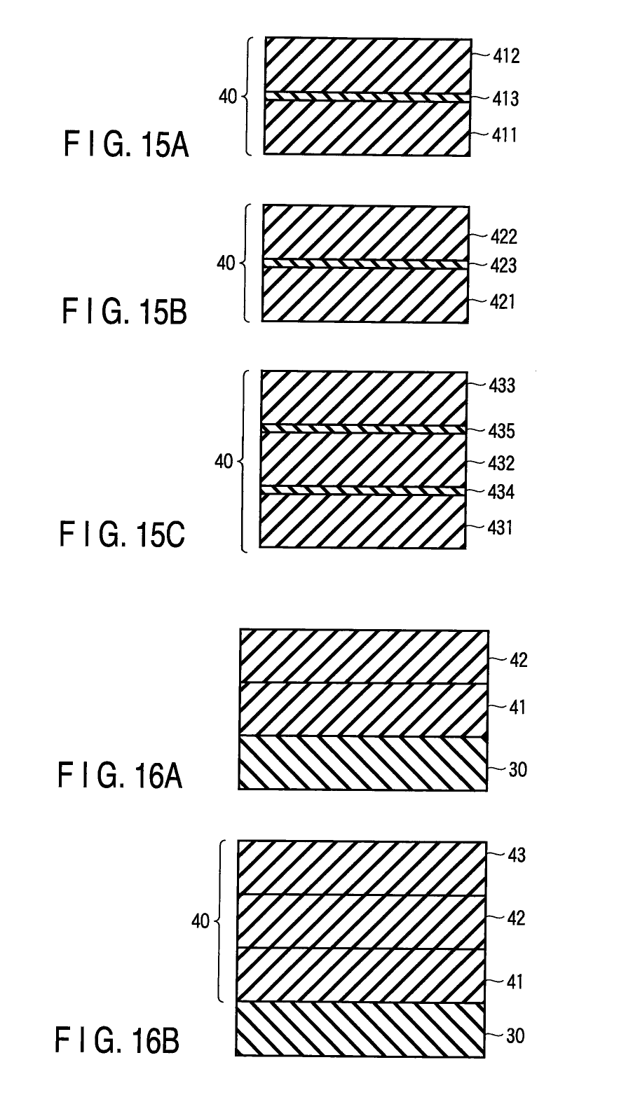

Furthermore, in the above-described embodiment, the block insulating film 40 is formed of the lower insulating film 41, the intermediate insulating film 42, and the upper insulating film 43. However, the configuration of the block insulating film 40 is not limited to the above-described one. In general, the block insulating film 40 includes a first insulating film containing a metal element and oxygen as main components, a second insulating film containing silicon and oxygen as main components, and an interface layer formed at the interface between the first insulating film and the second insulating film. The interface layer has a higher trap state density than the first insulating film and the second insulating film. The first insulating film has a higher dielectric constant than the second insulating film. For example, such a metal oxide film as described above in the first embodiment may be used as the first insulating film. Such a silicon oxide film as described above in the first embodiment may be used as the second insulating film. Furthermore, such interface layers as described above in the first embodiment may be used. Specific modifications will be described below with reference to FIGS. 15A, 15B, and 15C.

FIG. 15A is a sectional view schematically showing the configuration of a first modification of a block insulating film 40. As shown in FIG. 15A, the block insulating film 40 has a lower insulating film (first insulating film) 411 containing a metal element and oxygen as main components, an upper insulating film (second insulating film) 412 containing silicon and oxygen as main components, and an interface layer 413 formed at the interface between the lower insulating film 411 and the upper insulating film 412. Even in this configuration, as is the case with the above-described embodiment, the interface layer 413, having a high trap state density, allows the barrier effect on the possible tunnel current to be improved. Therefore, the possible leakage current from the block insulating film can be inhibited.

FIG. 15B is a sectional view schematically showing the configuration of a second modification of a block insulating film 40. As shown in FIG. 15B, the block insulating film 40 has a lower insulating film (second insulating film) 421 containing silicon and oxygen as main components, an upper insulating film (first insulating film) 422 containing a metal element and oxygen as main components, and an interface layer 423 formed at the interface between the lower insulating film 421 and the upper insulating film 422. Even in this configuration, as is the case with the above-described embodiment, the interface layer 423, having a high trap state density, allows the barrier effect on the possible tunnel current to be improved. Therefore, the possible leakage current from the block insulating film can be inhibited.

FIG. 15C is a sectional view schematically showing the configuration of a third modification of a block insulating film 40. As shown in FIG. 15C, the block insulating film 40 has a lower insulating film (first insulating film) 431 containing a metal element and oxygen as main components, an intermediate insulating film (second insulating film) 432 containing silicon and oxygen as main components, an upper insulating film (first insulating film) 433 containing a metal element and oxygen as main components, an interface layer 434 formed at the interface between the lower insulating film 431 and the intermediate insulating film 432, and an interface layer 435 formed at the interface between the upper insulating film 433 and the intermediate insulating film 432. Even in this configuration, as is the case with the above-described embodiment, the interface layers 434 and 435, having a high trap state density, allow the barrier effect on the possible tunnel current to be improved. Therefore, the possible leakage current from the block insulating film can be inhibited.

The block insulating film 40 according to the above-described first to third modifications can be formed using methods similar to those described in the first to fourth specific examples.

Alternatively, the block insulating film 40 may have a stack structure with at least four layers provided that the block insulating film 40 includes a first insulating film containing a metal element and oxygen as main components, a second insulating film containing silicon and oxygen as main components, and an interface layer formed at the interface between the first insulating film and the second insulating film. For example, a structure may be adopted in which an insulating film A containing a metal element and oxygen as main components, an insulating film B containing silicon and oxygen as main components, an insulating film C containing a metal element and oxygen as main components, an insulating film D containing silicon and oxygen as main components, and an insulating film E containing a metal element and oxygen as main components are stacked in this order, with an interface layer with a high trap state density formed between the insulating films A and B, between the insulating films B and C, between the insulating films C and D, and between the insulating films D and E.

### Embodiment 2

Now, a second embodiment of the present invention will be described. The basic configuration of a semiconductor device according to the present embodiment and a basic method for manufacturing the semiconductor device are similar to those in the first embodiment. Thus, the matters described in the first embodiment will not be described below.

FIGS. 16A and 16B are sectional views schematically showing a part of a method for manufacturing a semiconductor device according to the present embodiment. A basic manufacturing method according to the present embodiment is similar to that shown in FIGS. 1A and 1B to FIGS. 5A and 5B. Thus, a method for manufacturing a block insulating film will be mainly described.

A charge storage insulating film 30 is formed in the step shown in FIGS. 1A and 1B. Then, as shown in FIG. 16A, a metal oxide film serving as a lower insulating film 41 in a block insulating film is formed on the charge storage insulating film 30. An aluminum oxide film (alumina film) is used as the metal oxide film. Specifically, an alumina film 41 of thickness about 4 nm is formed at a deposition temperature of 300° C. by the ALD method using trimethyl aluminum and steam as a source gas. Thermal treatment is carried out in a nitrogen atmosphere at 1,000° C. for one minute. A silicon oxide film serving as an intermediate insulating film 42 in the block insulating film is then formed on the alumina film 41. Specifically, a silicon oxide film 42 of thickness about 3 nm is formed at a deposition temperature of 800° C. by the CVD method using nitrogen monoxide and dichlorosilane as a source gas. Thermal treatment is thereafter carried out on the stack film of the alumina film (lower insulating film) 41 and the silicon oxide film (intermediate insulating film) 42 in an oxidizing atmosphere. Specifically, the thermal treatment is carried out in an atmosphere containing steam (H₂O) of 2 kPa at 800° C. for one minute.

Then, as shown in FIG. 16B, a metal oxide film serving as an upper insulating film 43 in the block insulating film is formed on the silicon oxide film 42. An alumina film is used as the metal oxide film. An alumina film 43 of thickness about 4 nm is formed by the ALD method. Specific deposition conditions for the alumina film 43 are the same as those for the above-described alumina film 41. Moreover, thermal treatment is carried out in a nitrogen atmosphere at 1,000° C. for one minute. The thermal treatment allows an interface layer to be formed as described in the first embodiment. However, the interface layer is not shown in the drawings.

Subsequent steps are similar to those shown in FIGS. 2A and 2B to FIGS. 5A and 5B. Thus, such a memory cell transistor as shown in FIGS. 5A and 5B is formed.

When the silicon oxide film 42 is formed on the alumina film 41, the alumina film 41 is reduced by hydrogen and chloride contained in a deposition gas (source gas) for the silicon oxide film 42. Thus, oxygen vacancy may occur in the alumina film 41. As a result, the defect in the alumina film 41 may increase a leakage current, thus degrading the charge retention characteristic of the memory cell. In the present embodiment, after the silicon oxide film 42 is formed on the alumina film 41, the thermal treatment is carried out in the atmosphere containing steam (H₂O). The thermal treatment compensates for the oxygen vacancy in the alumina film 41. This allows the possible increase in leakage current caused by the defect in the alumina film 41 to be inhibited. Thus, charge retention characteristic of the memory cell can be improved. Therefore, the possible leakage current from the block insulating film 40 can be inhibited, providing a reliable nonvolatile semiconductor memory with excellent characteristics.

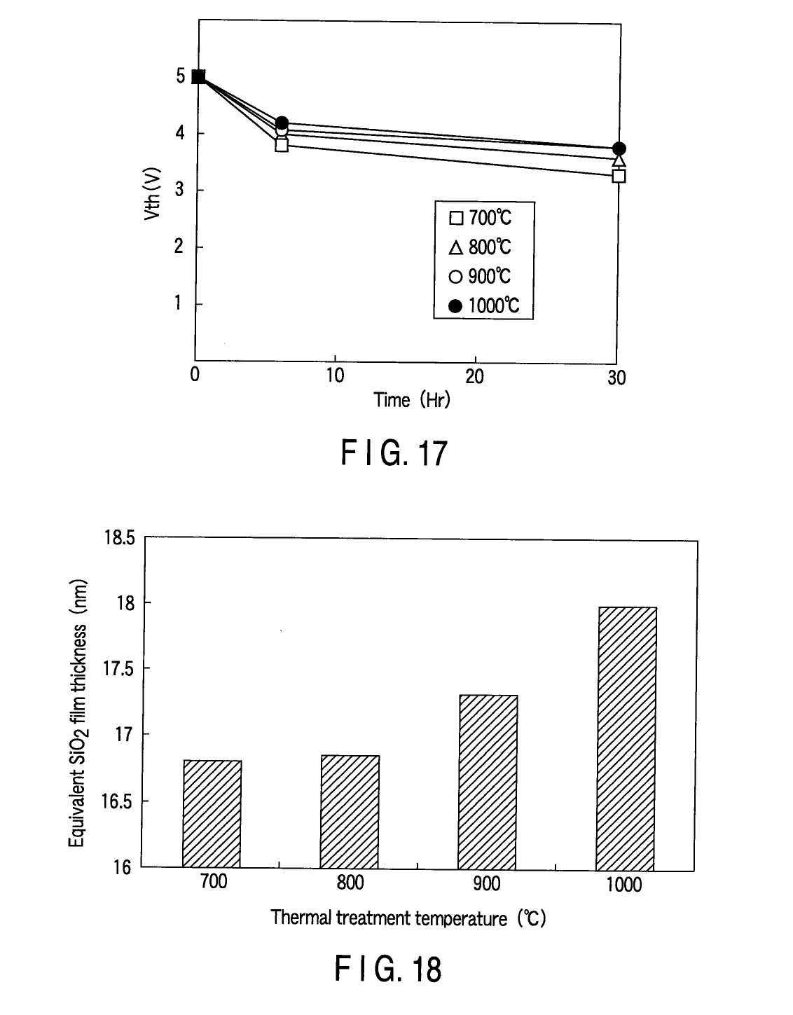

FIG. 17 is a diagram showing the dependence of the charge retention characteristic on the thermal treatment temperature observed when the thermal treatment is carried out in the above-described steam atmosphere. FIG. 18 is a diagram showing the relationship between the thermal treatment temperature in the above-described steam atmosphere and the electrical film thickness (Equivalent silicon oxide film thickness) of the whole insulating film (tunnel insulating film, charge storage insulating film, and block insulating film).

As shown in FIG. 17, an increase in thermal treatment temperature improves the charge retention characteristic. On the other hand, the electrical film thickness of the whole insulating film increases drastically at a thermal treatment temperature of at least 900° C. This is expected to be because steam passes through the block insulating film to oxidize the charge storage insulating film. Thus, the temperature of the thermal treatment in the steam atmosphere is preferably within the range of 700 to 900° C.

In the above-described embodiment, the thermal treatment is carried out in the atmosphere containing steam (H₂O). However, in general, the thermal treatment can be carried out in an oxidizing atmosphere. For example, the thermal treatment can also be carried out in an atmosphere containing an oxygen gas (O₂ gas), an ozone gas (O₃), or oxygen radicals. However, the thermal treatment is preferably carried out in the atmosphere containing steam for the following reason.

In the silicon oxide film, the diffusion reaction of steam (H₂O) progresses with the network of Si—O bonds substituted. Thus, the steam has a great ability to repair the oxygen vacancy. Furthermore, the steam exhibits a relatively large diffusion length in the insulating film containing oxygen. Thus, the steam is suitable for improving the alumina film under the silicon oxide film. Moreover, the steam exerts weaker oxidizing power than ozone or oxygen radicals and is thus unlikely to oxidize the charge storage insulating film during the thermal treatment. The oxidized charge storage insulating film may reduce the trap density, degrading the write/erase characteristic of the memory cell. Consequently, the thermal treatment is preferably carried out in the atmosphere containing steam.

In the above-described embodiment, the alumina film is used as the metal oxide film for the lower insulating film 41 and the upper insulating film 43. However, a hafnium oxide film, a zirconium oxide film, or the like may be used. Each of the lower insulating film 41 and the upper insulating film 43 may generally be an insulating film containing at least a metal element and oxygen as main components. Additionally, in the above-described embodiment, the silicon oxide film is used as the intermediate insulating film 42. However, the intermediate insulating film 42 may generally be an insulating film containing at least silicon and oxygen as main components. The intermediate insulating film 42 may contain an element such as nitrogen.

Furthermore, the method according to the above-described embodiment is particularly effective when the deposition gas (source gas) for the silicon oxide film (intermediate insulating film) 42 contains at least one of hydrogen and chloride.

In the above-described embodiment, the block insulating film 40 is formed of the lower insulating film 41, the intermediate insulating film 42, and the upper insulating film 43. However, the configuration of the block insulating film 40 is not limited to the one according to the above-described embodiment. The method according to the above-described embodiment is applicable provided that the step of forming the block insulating film 40 includes a step of forming a second insulating film containing silicon and oxygen as main components, on a first insulating film containing a metal element and oxygen as main components. Thus, the block insulating film 40 may have a two-layer structure with the first insulating film and the second insulating film or a stack structure with at least four layers. The first insulating film preferably has a higher dielectric constant than the second insulating film.

### Embodiment 3

Now, a third embodiment of the present invention will be described. The basic configuration of a semiconductor device according to the present embodiment and a basic method for manufacturing the semiconductor device are similar to those in the first embodiment. Thus, the matters described in the first embodiment will not be described below.

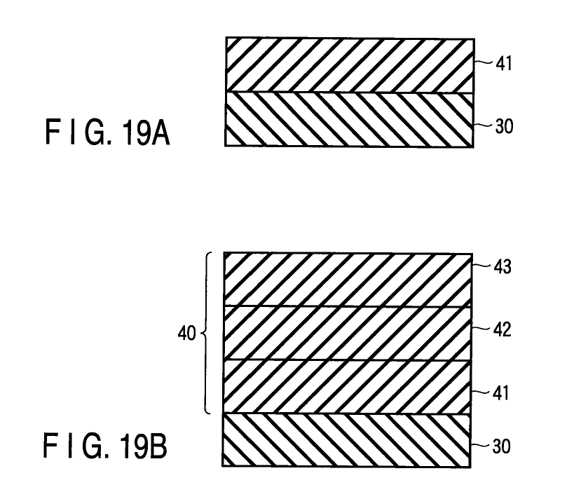

FIGS. 19A and 19B are sectional views schematically showing a part of a method for manufacturing a semiconductor device according to the present embodiment. A basic manufacturing method according to the present embodiment is similar to that shown in FIGS. 1A and 1B to FIGS. 5A and 5B. Thus, a method for manufacturing a block insulating film will be mainly described.

A charge storage insulating film 30 is formed in the step shown in FIGS. 1A and 1B. Then, as shown in FIG. 19A, a metal oxide film serving as a lower insulating film 41 in a block insulating film is formed on the charge storage insulating film 30. An aluminum oxide film (alumina film) is used as the metal oxide film. Specifically, an alumina film 41 of thickness about 4 nm is formed at a deposition temperature of 300° C. by the ALD method using trimethyl aluminum and steam (H₂O) as a source gas. That is, the alumina film 41 is formed in a deposition atmosphere containing steam, exerting relatively weak oxidizing power, as an oxidizing agent.

Then, thermal treatment is carried out in a nitrogen atmosphere at 1,000° C. for one minute. A silicon oxide film serving as an intermediate insulating film 42 in the block insulating film is then formed on the alumina film 41. Specifically, a silicon oxide film 42 of thickness about 3 nm is formed at a deposition temperature of 800° C. by the CVD method using nitrogen monoxide and dichlorosilane as a source gas. A metal oxide film serving as an upper insulating film 43 in the block insulating film is subsequently formed on the silicon oxide film 42. An alumina film is used as the metal oxide film. Specifically, an alumina film 43 of thickness about 4 nm is formed at a deposition temperature of 300° C. by the ALD method using trimethyl aluminum and ozone (O₃) as a source gas. That is, the alumina film 43 is formed in a deposition atmosphere containing ozone, exerting relatively strong oxidizing power, as an oxidizing agent. Thermal treatment is further carried out in a nitrogen atmosphere at 1,000° C. for one minute. The thermal treatment allows an interface layer to be formed as described in the first embodiment. However, the interface layer is not shown in the drawings.

Subsequent steps are similar to those shown in FIGS. 2A and 2B to FIGS. 5A and 5B. Thus, such a memory cell transistor as shown in FIGS. 5A and 5B is formed.

As described above, in the present embodiment, ozone is used as an oxidizing agent to form the alumina film (upper insulating film) 43. Ozone exerts high oxidizing power and thus enables a reduction in oxygen vacancy or remaining impurities in the alumina film. This allows inhibition of a leakage current resulting from a defect in the alumina film and the possible detrapping of electrons trapped in the defect. Thus, a proper charge retention characteristic can be obtained. However, when ozone is used as an oxidizing agent to form the alumina film (lower insulating film) 41, the charge storage insulating film (silicon nitride film) 30 may be oxidized. The oxidized charge storage insulating film may reduce the trap density, degrading the write/erase characteristic of the memory cell.

In the present embodiment, steam (H₂O), exerting weak oxidizing power, is used as an oxidizing agent to form the alumina film (lower insulating film) 41. This allows the charge storage insulating film 30 to be inhibited from being oxidized. On the other hand, ozone (O₃), exerting strong oxidizing power, is used as an oxidizing agent to form the alumina film (upper insulating film) 43. As described above, this allows the leakage current resulting from a defect in the alumina film and the possible detrapping of charges to be inhibited. Thus, a proper charge retention characteristic can be obtained. Therefore, the present embodiment enables the charge storage insulating film 30 to be prevented from being oxidized, and allows the possible leakage current from the block insulating film 40 to be inhibited. As a result, a reliable nonvolatile semiconductor memory with excellent characteristic can be obtained.

In the above-described embodiment, the alumina film is used as the metal oxide film for the lower insulating film 41 and the upper insulating film 43. However, a hafnium oxide film, a zirconium oxide film, or the like may be used. Each of the lower insulating film (first insulating film) 41 and the upper insulating film (third insulating film) 43 may generally be an insulating film containing at least a metal element and oxygen as main components. Additionally, in the above-described embodiment, the silicon oxide film is used as the intermediate insulating film 42. However, the intermediate insulating film (second insulating film) 42 may generally be an insulating film containing at least silicon and oxygen as main components. The intermediate insulating film 42 may contain an element such as nitrogen. Each of the first and third insulating films preferably has a higher dielectric constant than the second insulating film.

In the above-described embodiment, steam, which exerts weak oxidizing power, is used to form the alumina film (lower insulating film) 41, whereas ozone, which exerts strong oxidizing power, is used to form the alumina film (upper insulating film) 43. However, the present embodiment is not limited to this method. In general, the lower insulating film (first insulating film) 41 containing a metal element and oxygen as main components may be formed in a first deposition atmosphere with relatively weak oxidizing power. The upper insulating film (third insulating film) 43 containing the metal element and oxygen as main components may be formed in a second deposition atmosphere exerting stronger oxidizing power than the first deposition atmosphere. Specifically, the following two methods are available: one (first method) for varying the type of the oxidizing agent between the first deposition atmosphere and the second deposition atmosphere and one (second method) for varying the temperature between the first deposition atmosphere and the second deposition atmosphere.

In the first method, a first oxidizing agent exerting relatively weak oxidizing power is used in the first deposition atmosphere. A second oxidizing agent exerting stronger oxidizing power than the first oxidizing agent is used in the second deposition atmosphere. Steam (H₂O), oxygen gas (O₂ gas), or the like may be used as the first oxidizing agent. Ozone gas (O₃), oxygen radicals, or the like may be used as the second oxidizing agent.

In the second method, the temperature of the second deposition atmosphere is set to be higher than that of the first deposition temperature. In this case, the same oxidizing agent may be used for both the first and second deposition atmospheres.

### Embodiment 4

Now, a fourth embodiment of the present invention will be described. In the present embodiment, the configuration of the block insulating film and the method for manufacturing the block insulating film described above in the first to third embodiments are applied to a nonvolatile semiconductor memory having a three-dimensional structure called BiCS (Bit Cost Scalable). Thus, the matters described in the first to third embodiments will not be described below.

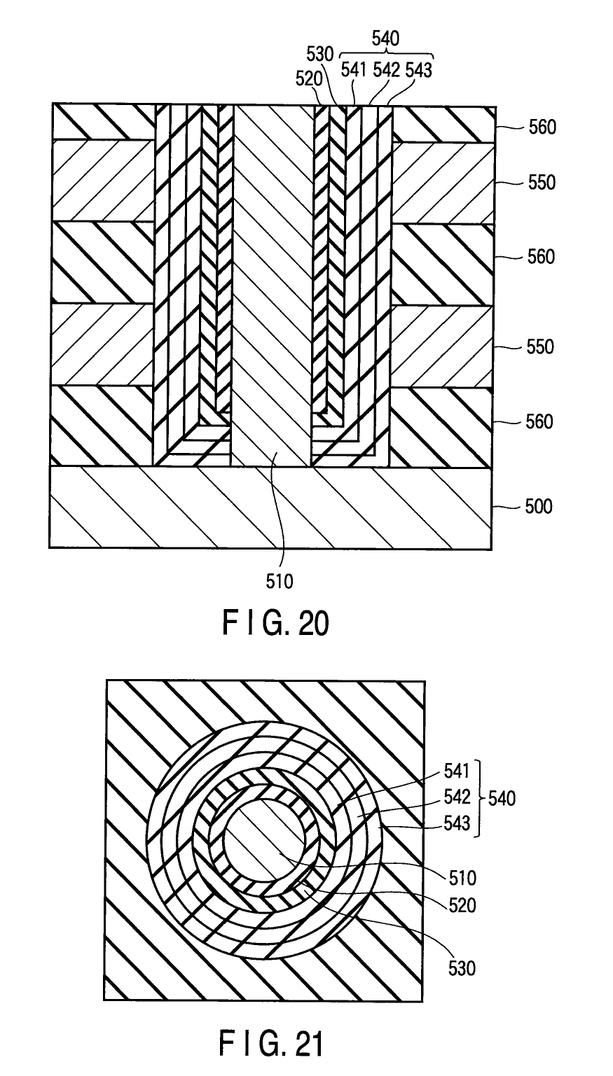

FIG. 20 is a sectional view schematically showing the basic configuration of a semiconductor device according to the present embodiment. FIG. 21 is a plan view schematically showing the basic configuration of the semiconductor device according to the present embodiment. Now, with reference to FIGS. 20 and 21, the basic configuration of the semiconductor device according to the present embodiment will be described.

As shown in FIGS. 20 and 21, a columnar semiconductor region (silicon region) 510 serving as an active region is formed on a substrate 500. A tunnel insulating film 520, a charge storage insulating film 530, and a block insulating film 540 are formed around the periphery of the semiconductor region 510. That is, the tunnel insulating film 520 is formed on the surface of the semiconductor region 510. The charge storage insulating film 530 is formed on the surface of the tunnel insulating film 520. The block insulating film 540 is formed on the surface of the charge storage insulating film 530.

The block insulating film 540 has an inner insulating film 541, an intermediate insulating film 542, and an outer insulating film 543. The inner insulating film 541, the intermediate insulating film 542, and the outer insulating film 543 correspond to the lower insulating film 41, intermediate insulating film 42, and upper insulating film 43 shown in the first to third embodiments. The various configurations and various formation methods described in the first to third embodiments are applicable to the block insulating film 540.

A stack structure with a plurality of control gate electrodes 550 and a plurality of interlayer insulating films 560 is formed around the periphery of the block insulating film 540, that is, on the surface of the block insulating film 540. The numbers of the control gate electrodes 550 and the interlayer insulating films 560 are appropriately determined.

As is apparent from the above description, the above-described semiconductor device is configured such that a plurality of memory cells are stacked in the vertical direction. Thus, the number of memory cells per unit area can be increased.

Now, with reference to FIGS. 20 and 21, a basic method for manufacturing a semiconductor device according to the present embodiment will be described.

First, a stack film with control gate electrode films 550 and interlayer insulating films 560 is formed on the substrate 500. A hole is subsequently formed so as to reach the substrate 500. A block insulating film 540, a charge storage insulating film 530, and a tunnel insulating film 520 are sequentially formed along the side surface and bottom surface of the hole. Portions of the tunnel insulating film 520, charge storage insulating film 530, and block insulating film 540 which are formed on the bottom surface of the hole are removed. A semiconductor region 510 is further formed in the hole in which the tunnel insulating film 520, the charge storage insulating film 530, and the block insulating film 540 are formed. Wiring and the like are subsequently formed to obtain a semiconductor device (nonvolatile semiconductor memory).

The correspondence between the present embodiment and each of the first to third embodiments will be described.

First, a case will be described in which the block insulating film 40 as described in the first embodiment is applied to the block insulating film 540 according to the present embodiment.

As already described, the inner insulating film 541, intermediate insulating film 542, and outer insulating film 543 according to the present embodiment correspond to the lower insulating film 41, intermediate insulating film 42, and upper insulating film 43 shown in the first to third embodiments. In the present embodiment, as is the case with FIG. 6 for the first embodiment, an interface layer (not shown in the drawings and corresponding to the interface layer 44 in FIG. 6) is formed between the inner insulating film 541 and the intermediate insulating film 542. An interface layer (not shown in the drawings and corresponding to the interface layer 45 in FIG. 6) is formed between the outer insulating film 543 and the intermediate insulating film 542. The block insulating film 540 configured as described above enables effects similar to those described in the first embodiment to be exerted.

As the block insulating film 540, a component similar to the corresponding component described in the first embodiment can be used. To form the block insulating film 540, a method similar to any of those described in the first embodiment (the methods described in Specific Examples 1 to 4) or an easily conceivable method may be used. Moreover, any of the various configurations as shown in FIGS. 15A, 15B, and 15C for the first embodiment may be used as the configuration of the block insulating film 540.

Now, a case will be described in which the block insulating film 40 as described in the second embodiment is applied to the block insulating film 540 according to the present embodiment.

In the present embodiment, a block insulating film 540 is formed by a method similar to that shown in FIGS. 16A and 16B for the second embodiment. Specifically, an outer insulating film 543 and an intermediate insulating film 542 are formed. The outer insulating film 543 and the intermediate insulating film 542 are thermally treated in an oxidizing atmosphere by a method similar to the corresponding method described in the first embodiment. An inner insulating film 541 is thereafter formed. Thus, the block insulating film 540 with the inner insulating film 541, the intermediate insulating film 542, and the outer insulating film 543 is formed. The block insulating film 540 formed by this method enables effects similar to those described in the second embodiment to be exerted.

Now, a case will be described in which the block insulating film 40 as described in the third embodiment is applied to the block insulating film 540 according to the present embodiment.

In the present embodiment, a block insulating film 540 is formed by a method similar to that shown in FIGS. 19A and 19B for the third embodiment. Specifically, an outer insulating film 543 is formed in a deposition atmosphere with relatively weak oxidizing power. An intermediate insulating film 542 is then formed. An inner insulating film 541 is formed in a deposition atmosphere with relatively strong oxidizing power. Thus, the block insulating film 540 with the inner insulating film 541, the intermediate insulating film 542, and the outer insulating film 543 is formed.

The block insulating film 540 formed by the above-described method enables the following effects to be exerted. That is, the inner insulating film 541 is deposited in the atmosphere with relatively strong oxidizing power. Thus, the inner insulating film 541 with proper characteristics can be obtained. Furthermore, the outer insulating film 543 is deposited in the atmosphere with relatively weak oxidizing power. Thus, an underlying region for the outer insulating film 543 can be inhibited from being oxidized. Specifically, a control gate electrode 550 formed in the underlying region can be inhibited from being oxidized. Therefore, a possible back tunneling current during erasure is reduced to improve erase characteristics.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a tunnel insulating film formed on a surface of a semiconductor region;
a charge storage insulating film formed on a surface of the tunnel insulating film;
a block insulating film formed on a surface of the charge storage insulating film; and
a control gate electrode formed on a surface of the block insulating film,
wherein the block insulating film includes a first insulating film containing a metal element and oxygen as main components, a second insulating film containing silicon and oxygen as main components, and an interface layer formed between the first insulating film and the second insulating film and containing the metal element, silicon, and oxygen as main components.

2. The semiconductor device according to claim 1, wherein the first insulating film has a higher dielectric constant than the second insulating film.

3. The semiconductor device according to claim 1, wherein the first insulating film has a higher trap state density than the second insulating film, and
the interface layer has a higher trap state density than the first insulating film.

4. The semiconductor device according to claim 1, wherein the block insulating film further includes a third insulating film containing the metal element and oxygen as main components, and another interface layer formed between the second insulating film and the third insulating film and containing the metal element, silicon, and oxygen as main components, and
the second insulating film is formed between the first insulating film and the third insulating film.

5. A semiconductor device comprising:
a tunnel insulating film formed on a surface of a semiconductor region;
a charge storage insulating film formed on a surface of the tunnel insulating film;
a block insulating film formed on a surface of the charge storage insulating film; and
a control gate electrode formed on a surface of the block insulating film,
wherein the block insulating film includes a first insulating film containing a metal element and oxygen as main components, a second insulating film containing silicon and oxygen as main components, and an interface layer formed between the first insulating film and the second insulating film and containing nitrogen, and
the interface layer has a higher nitrogen concentration than each of the first insulating film and the second insulating film.

6. The semiconductor device according to claim 5, wherein the first insulating film has a higher dielectric constant than the second insulating film.

7. The semiconductor device according to claim 5, wherein the first insulating film has a higher trap state density than the second insulating film, and
the interface layer has a higher trap state density than the first insulating film.

8. The semiconductor device according to claim 5, wherein the block insulating film further includes a third insulating film containing the metal element and oxygen as main components, and another interface layer formed between the second insulating film and the third insulating film and containing nitrogen,
the second insulating film is formed between the first insulating film and the third insulating film, and
the another interface layer has a higher nitrogen concentration than each of the second insulating film and the third insulating film.

9. A semiconductor device comprising:
a tunnel insulating film formed on a surface of a semiconductor region;
a charge storage insulating film formed on a surface of the tunnel insulating film;
a block insulating film formed on a surface of the charge storage insulating film; and
a control gate electrode formed on a surface of the block insulating film,
wherein the block insulating film includes a first insulating film containing a metal element and oxygen as main components, a second insulating film containing silicon and oxygen as main components, and an interface layer formed between the first insulating film and the second insulating film and containing a predetermined element selected from inert gas elements and halogen elements, and
the predetermined element in the interface layer has a higher concentration than that in each of the first insulating film and the second insulating film.

10. The semiconductor device according to claim 9, wherein the first insulating film has a higher dielectric constant than the second insulating film.

11. The semiconductor device according to claim 9, wherein the first insulating film has a higher trap state density than the second insulating film, and
the interface layer has a higher trap state density than the first insulating film.

12. The semiconductor device according to claim 9, wherein the block insulating film further includes a third insulating film containing the metal element and oxygen as main components, and another interface layer formed between the second insulating film and the third insulating film and containing the predetermined element,
the second insulating film is formed between the first insulating film and the third insulating film, and
the predetermined element in the another interface layer has a higher concentration than that in each of the second insulating film and the third insulating film.

13. A method for manufacturing a semiconductor device comprising a tunnel insulating film formed on a surface of a semiconductor region, a charge storage insulating film formed on a surface of the tunnel insulating film, a block insulating film formed on a surface of the charge storage insulating film, and a control gate electrode formed on a surface of the block insulating film,
forming the block insulating film comprising:
forming a first insulating film containing a metal element and oxygen as main components;
forming a second insulating film containing silicon and oxygen as main components, on a surface of the first insulating film; and
carrying out thermal treatment on the first insulating film and the second insulating film in an oxidizing atmosphere.

14. The method according to claim 13, wherein when the second insulating film is formed, the first insulating film is reduced and oxygen vacancy is formed in the first insulating film, and
the thermal treatment in the oxidizing atmosphere compensates for the oxygen vacancy in the first insulating film.

15. The method according to claim 13, wherein the oxidizing atmosphere contains at least one of steam, oxygen gas, ozone gas, and an oxygen radical.

16. The method according to claim 13, further comprising forming a third insulating film containing the metal element and oxygen as main components, on a surface of the second insulating film thermally treated in the oxidizing atmosphere.

17. A method for manufacturing a semiconductor device comprising a tunnel insulating film formed on a surface of a semiconductor region, a charge storage insulating film formed on a surface of the tunnel insulating film, a block insulating film formed on a surface of the charge storage insulating film, and a control gate electrode formed on a surface of the block insulating film,
forming the block insulating film comprising:
forming a first insulating film containing a metal element and oxygen as main components, in a first depositing atmosphere;
forming a second insulating film containing silicon and oxygen as main components, on a surface of the first insulating film; and
forming a third insulating film containing a metal element and oxygen as main components, on a surface of the second insulating film in a second depositing atmosphere exerting higher oxidizing power than the first depositing atmosphere.

18. The method according to claim 17, wherein the first deposition atmosphere contains a first oxidizing agent, and
the second deposition atmosphere contains a second oxidizing agent exerting higher oxidizing power than the first oxidizing agent.

19. The method according to claim 17, wherein the second deposition atmosphere has a higher temperature than the first deposition atmosphere.
